(19) United States
(12) Patent Application Publication
(10) Pub. No.: US 2018/0277701 A1
(43) Pub. Date: Sep. 27, 2018

(54) Method of Manufacturing of a Solar Cell and Solar Cell Thus Obtained

(71) Applicant: Tempress IP B.V., Vaassen (NL)

(72) Inventors: Martijn Lenes, Vaassen (NL); Ronald Cornelis Gerard Naber, Vaassen (NL); Johannes Reinder Marc Luchies, Vaassen (NL); Albert Hasper, Vaassen (NL)

(73) Assignee: Tempress IP B.V., Vaassen (NL)

(21) Appl. No.: 15/762,507

(22) PCT Filed: Sep. 28, 2016
(86) PCT No.: PCT/NL2016/050665

§ 371 Date: Mar. 22, 2018

(30) Foreign Application Priority Data
Sep. 30, 2015 (NL) 2015533

(51) Int. Cl. H01L 31/068; H01L 31/18

(52) U.S. Cl. CPC H01L 31/0682; H01L 31/0684; H01L 31/182

(57) ABSTRACT

The method of manufacturing of a solar cell comprises the steps of: providing a semiconductor substrate (100) comprising an electrically conductive region (11) extending at a first side thereof; and providing a tunnelling oxide (13) by thermal oxidation followed by a boron doped polysilicon LPCVD deposited layer on the second side of the semiconductor substrate. Herein, the provision of the doped polysilicon layer (20) comprises depositing a multilayer stack of first sublayers (21, 22, 23) of silicon and second sublayers (31, 32) of boron dopant in alternation, and subsequent annealing. Thereafter the solar cell is finalized with passivation layers on at least the first side and suitable metallization layers on the emitter and base regions.

### FIELD OF THE INVENTION

The invention relates to a method of manufacturing a solar cell comprising the steps of:
Providing a semiconductor substrate with a first and a second side, which first side is intended as main side for receiving light;
depositing a tunnel dielectric on at least the second side of the semiconductor substrate;
depositing by means of Low Pressure Chemical Vapor Deposition a layer of doped silicon onto the second side of the substrate, separated from substrate by the tunnel dielectric;
annealing the layer of doped silicon
further processing of the substrate into a solar cell, i.e. provided with a back end;

The invention also relates to a solar cell device thus obtained.

The invention further relates to a low pressure chemical vapour deposition (LPCVD) apparatus.

### BACKGROUND OF THE INVENTION

The efficiency and lifetime of solar cells is reduced by the recombination of charge carriers. Such recombination particularly occurs at the surface, where the crystal lattice of the semiconductor substrate is disrupted. In order to limit surface recombination of charge carriers, it has been proposed to shield the contacts to the substrate from the underlying region defined in the substrate by means of a tunnel dielectric, such as a tunnel oxide. A tunnel oxide is a layer of oxide so thin that the probability of electron direct tunnelling across it is very high; typically the thickness of a tunnel oxide is less than about 3.0 nm. The contact surface of the contact to a tunnel dielectric is suitably a semiconductor material. The most common example is polysilicon, which can be deposited in a chemical vapour deposition apparatus. The polysilicon may be annealed after deposition to enhance its crystallinity and/or the sizes of its crystalline domains. In the late 1980s such structure was invented to make polysilicon emitters for bipolar devices in CMOS technology with phosphorus doped polysilicon, where the introduction of a thin dielectric layer, a tunnel dielectric, served as a very effective charge separation for electrons and holes, thus significantly improving current gain of these transistors. For solar cell devices, a similar structure has been proposed in the 1990s. In U.S. Pat. No. 5,057,439 it is proposed to use polysilicon emitters in solar cells.

Intrinsic polysilicon however is not a good conductor. Therefore, a dopant is usually added. When the polysilicon has a large surface area, it may contain domains of different conductivity, such as for instance suggested in U.S. Pat. No. 7,468,485. The n-type dopant is typically phosphorous and the p-type dopant is typically boron, even though other dopants are not excluded. Various methods of doping a material are known. The most common process for doping polysilicon is by means of diffusion. Herein, un-doped, intrinsic polysilicon is deposited. Thereafter a dopant is deposited in a manner to result in a silicate glass, typically borosilicate glass (BSG) or phosphosilicate glass (PSG). Subsequently, an anneal is done for instance at 950° C. during 1 hour. As a result hereof, the dopant diffuses into the polysilicon, which results in a sufficiently high conductivity. After this anneal, the polysilicon is contacted with the metallization. A suitable metallization scheme needs to be incorporated as known per se to the person skilled in the art. In this type of solar cells, where the metallization is indirectly connected to the substrate, by means of a tunnel dielectric, the contacts are ‘passivated’, meaning that much less of the cell current can recombine at the contacts. These contacts are therefore also referred to as ‘passivated contacts’. The term ‘passivated contact’ will also be used in cases, where the substrate does not contain an electrically conductive region of the same polarity as the boron doped polysilicon. In such a case, the boron doped polysilicon functions as emitter (or back surface field), forming a pn-junction with the substrate.

Unfortunately, the boron dopant has the tendency to segregate from the silicon, towards grain boundaries, and therewith to get liberated from the crystal lattice, and to diffuse further. This leads to poor passivation of the tunnel oxide. This is shown, for instance in FIG. 5 of US2014/166089A1. The constant boron concentration (10¹⁹ atoms/cc) along the depth indicates this. As a consequence, the surface recombination will again be an issue as before, and optionally even more substantial, due to the relatively high concentration of dopant in the polysilicon contact.

US2014/166089A1 proposes therefore the use of a silicon oxynitride as a tunnel dielectric, wherein the silicon oxynitride layer has a non-homogeneous distribution of nitrogen. The non-homogenous distribution means particularly that the nitrogen concentration at the side of the (polysilicon) emitter contact is at the highest, so as to constitute a barrier against the migration of the liberated boron atoms. In FIG. 5, US2014/166089 shows the result thereof. There is indeed a clear distinction between the boron concentration in the polysilicon film and in the underlying layers. However, the boron concentration reduces gradually from the top concentration of nearly 10²⁰ atoms/cc in the polysilicon layer to the background concentration in the silicon substrate at 10¹⁶ atoms/cc, which is the measurement threshold. The gradual reduction occurs in a surface zone of more than 0.1 micrometer (100 nm, i.e. 30-80 times the thickness of the tunnel dielectric). At a depth of 50 nm below the polysilicon/tunnel dielectric interface, the boron concentration is still as high as approximately 5·10¹⁸ atoms/cc. It thus appears that the nitride barrier slows down boron migration through the tunnel dielectric, but does not entirely stop it. It is therefore desired to provide an improved manufacturing process.

### SUMMARY OF THE INVENTION

It is therefore an object of the present invention to provide an improved manufacturing process for solar cells of the type mentioned in the opening paragraph, particularly the type of solar cells that have boron doped passivated contacts.

It is also an object of the present invention to provide a resulting solar cell.

It is a further object of the present invention to provide an improved chemical vapour deposition apparatus, with which the process according to the invention can be carried out.

According to a first aspect of the invention, the object is achieved in a method of manufacturing a solar cell, comprising the steps of: (1) providing a semiconductor substrate with a first and a second side, which first side is intended as main side for receiving light; (2) providing a tunnel dielectric on at least one side of the substrate; (3) providing a doped polysilicon layer onto the substrate, and (4) further processing of the substrate into a solar cell. Herein, the provision of the doped polysilicon layer comprises depositing a multilayer stack of first sub-layers and second dopant sub-layers by means of Low Pressure Chemical Vapour Deposition (LPCVD), and subsequent annealing of the multilayer stack into the doped polysilicon layer. The first sub-layers contain predominantly silicon. The second sub-layers contain boron.

According to a second aspect of the invention, a solar cell is provided that is obtainable with the method of the invention. This device typically comprises a doped polysilicon layer on the second side of the substrate, separated from the substrate with an optional electrically conductive region by a tunnel dielectric. Suitably, the doped polysilicon layer comprises a multilayer stack of first and second sub-layers in alternation, said stack defining a doping profile with doping peaks in the one or more second sub-layers.

In the present invention, the doped polysilicon layer is deposited as a multilayer stack of first layers and second layers. The first layers predominantly contain silicon and may be deposited in polycrystalline form, but alternatively or partially in amorphous form. The first layers are preferably deposited substantially without doping. However, it is not excluded that some dopant is included in the first layer. This may be the same dopant (boron) or a different dopant (gallium, but even phosphorus). If any dopant is applied, the doping level is suitably at most 1·10¹⁹ (atoms/cm³), whereas the average concentration in the doped polysilicon layer is suitably more than 5·10¹⁹ (atoms/cm³), preferably at least 10²⁰ (atoms/cm³). The term ‘predominantly contain’ is used herein to express that a further element could be present. However, this is in practice not foreseen, otherwise than some background doping.

The second layers are deposited as dopant layers. In a first embodiment, the dopant is deposited in a substantially pure form, i.e. as a boron layer. The deposited boron layers are presumably amorphous boron layers. In a second embodiment, the dopant is deposited in combination with a carrier. The carrier is suitably silicon, but could alternatively be another material, such as germanium. The boron content is then preferably at least 25 wt %, with the intention to deposit a mixed layer, for instance a boron silicide. More preferably, the boron content is at least 50 wt % or even at least 80 wt %. Subsequent annealing results in mixing of the boron and silicon. Annealing shows the creation of a boron doping profile throughout the polysilicon layer, with doping peaks in the second layers. The exact microstructural behaviour is not known. Rather than that the boron diffuses into the silicon, it could well be that the silicon mixes into the boron, initially forming a boron silicide.

In one embodiment, the anneal is carried out such that the resulting doping profile has a local minimum within a first silicon sublayer sandwiched between two adjacent boron sublayers defining the doping peaks, wherein the ratio of doping concentration in the doping peaks and the local minimum is at most 100, preferably at most 10. This embodiment has the advantage that the anneal temperature can be kept relatively low. That doping peaks remain, is a clear sign that the boron dopant does not just migrate to the interface with the tunnel dielectric. The relatively small ratio in doping concentration makes that the conductivity of the resulting polysilicon will be sufficiently high. In another embodiment, however, the boron concentration may become substantially uniform over the polysilicon layer. Still then, the second layer remains visible at a microscopic level, for instance by means of crystal lattice dimensions.

Surprisingly, it has been found that the present deposition method results in a boron spreading through the tunnel dielectric that is significantly reduced in comparison to the boron spreading through an oxynitride dielectric layer, as known from US2014/166089 (FIG. 6). As a consequence, it is not necessary to use an oxynitride as tunnel dielectric; a standard tunnel oxide can be used instead. This is particularly more efficient, since the standard tunnel oxide may be deposited in the same reaction chamber as the multilayer stack. Such deposition in a single process chamber additionally reduces temperature shocks to the substrates as well as handling, which may lead to yield loss and reduced lifetime or performance of the resulting solar cells. However, it is not excluded to use an oxynitride or another tunnel dielectric such as a Aluminum Oxide (AlOx, with x varying on the deposition conditions, generally, x=1-2, for instance x=1.5). Such alternative tunnel dielectric, for instance but not exclusively aluminium oxide, is suitably deposited in an atomic layer deposition apparatus (ALD).

In a first embodiment, the method is carried out in a single reaction chamber through variation of the introduction of precursor gases into the reaction chamber. These precursor gases are known per se. Suitable examples are silane and diborane. This has the advantage that the substrates do not need to be removed from the reaction chamber and that the operation conditions in the reaction chamber, particularly temperature and pressure remain constant, thus minimizing thermal shocks that the substrate undergoes. A preferred process is low-pressure chemical vapour deposition (LPCVD), wherein the pressure is carried out at sub-atmospheric pressures, for instance 30-100 mbar. Alternatively the method is carried out at atmospheric pressure. The reaction temperature is suitably in the range of 500-750° C. A temperature up to 650° C. or even in the range of 520-600° C. appears particularly suitable, since both the polysilicon and the amorphous boron may be applied at such temperatures.

In a further embodiment, silicon precursor gas is introduced into the reaction chamber in first periods and dopant precursor gas is introduced in second periods, thereby forming alternating layers consisting of mainly silicon and layers consisting of mainly the dopant. Suitably, the introduction of silicon precursor gas is discontinued during the second periods. Optionally, the reaction chamber is emptied, at least substantially, from silicon precursor gas prior to the introduction of dopant precursor gas at the start of a second period. The removal of silicon precursor gas is most effectively achieved when operating the reaction chamber at reduced pressure, i.e. in a LPCVD apparatus. One suitable manner of removal is further the introduction of a cleaning gas, such as H₂ or N₂ in a cleaning period between the first and the second period. However it is not deemed necessary to remove any remaining dopant precursor gas, such as diborane, at the end of the second period.

Preferably, the second periods are shorter than the first periods. Suitably, the second periods have a length of at most 10% of the first periods. It has been found that the amount of boron needed is rather limited. This is particularly controlled by means of the duration of the deposition periods. While it is in principle possible to deposit all boron in a single second period, it is deemed more favourable to apply at least two second periods, i.e. therewith obtaining a multilayer stack with at least two second sublayers, i.e. particularly containing boron. These second sublayers are in an important embodiment sandwiched between first sublayers, so that the boron sublayer is not present at an outer surface of the resulting doped polysilicon layer. Alternatively, the multilayer stacks end with a boron sublayer as the outer surface layer. This is however not preferred. The thickness of all the first layers does not need to be the same. Particularly, the bottom first layer and/or the top first layer may have a different thickness.

Preferably, the first and second period are chosen such that a sub-stack of a first and a second sublayer has a thickness of at most 50 nm, at most 20 nm or even at most 10 nm. The number of substacks is suitably in the range of 1-100, preferably 2-75, more preferably 5-50. A larger number of sub-stacks is preferred, as the overall uniformity of the dopant over the doped polysilicon after an anneal is better.

In one embodiment, the deposition process of the multilayer stack, and typically the complete method, is carried out for a batch of semiconductor substrates. As known to the skilled person, such substrates are thereto arranged on a tool known as a boat at a suitable spacing between adjacent substrates. Particularly, it has been found that the spacing is at most 8 mm, more preferably at most 5 mm. Such a narrow spacing has been found to improve the uniformity in the thickness of the resulting doped silicon layer over the substrate. It is believed that the arrangement at a small spacing leads to a more uniform distribution of the gaseous species and/or temperature within the reactor chamber. Such uniform distribution is particularly desired for boron dopants such as diborane species, since these dopants increases the effective growth rate of silicon, thereby causing significant non-uniform layers. These non-uniform layers can cause non-homogeneous sheet resistivity distribution along the solar cell surface, which will make it more difficult to etch, and to apply metal contacts which may both adversely affect the cell efficiency. It is found that at decreasing distances the standard deviation of the sheet resistivity improves and becomes very good, whereas at large distances the standard deviation is less optimal.

In Table 1 the results are shown for different wafer distances. For continuously doped polysilicon it is clear there is no good standard deviation possible. For multi-layer doped polysilicon layer the sheet resistivity is well controlled and the standard deviation decreases with decreased wafer distances showing that multilayer doped polysilicon can be applied for solar cells.

An overall layer thickness of the resulting doped polysilicon layer in the order of 10-400 nm is deemed suitable for use of passivated contacts at the rear side of the semiconductor substrate, i.e. the side to be assembled to a carrier. A overall layer thickness of 50-300 nm is preferred. The metal contact may be provided with a suitable metallisation, optionally in the form of screen printed silver or aluminium, as a silicide, such as Ni-silicide, a sputtered metal or in the form of a plated metal for instance a nickel-copper stack, to ensure a good contact with connecting materials using in assembly, such as electrically conductive adhesive and solder. It is deemed feasible that a plurality of contacts is applied to the rear side, some for use as emitter contact and others for use as back surface contacts, depending on the type of solar cell structure. In another suitable embodiment, the layer thickness for a doped polysilicon layer on top of a tunnel dielectric is in the range of 10-100 nm, preferably 20-80 nm or 20-50 nm. That is deemed sufficient, for instance at the second side in case that a p-type substrate is used. Such small thickness may also be feasible in combination with an electrically conductive layer directly on top of or a conductive region at the top side of the semiconductor substrate. Such electrically conductive layer or region serves for lateral conduction, Such electrically conductive layer may in itself be a boron doped polysilicon layer.

A thickness of less than 100 nm or even at most 50 nm is deemed an option for use at the front side, i.e. the side to be exposed to radiation of the sun. Such a thickness may also be attractive for use as a lateral conduction. Bigger thicknesses tend to be disadvantageous at the front side, particularly when applied over a large surface area, since the optical transparency of doped polysilicon is limited, and thus the efficiency of the solar cell rapidly decreases. It is one advantage of the process of the invention that doped polysilicon layers with low thickness may be provided, also with a sufficiently uniform doping and without the risk of damaging the underlying tunnel dielectric. In fact, alternative processes such as diffusion and implantation require a high anneal temperature of 900 degrees Celcius or more and a significant duration for boron doped regions. This will be clearly detrimental for an underlying tunnel dielectric when the thickness of the polysilicon is reduced. According to the invention, the provision of such a thin doped polysilicon layer without damaging the underlying tunnel dielectric is well feasible. Moreover, because of the small thickness and the regularity created by the thin layers, the crystalline domains of the polysilicon will likely grow, which again improves the optical transparency of the doped polysilicon layer.

In again a further embodiment, the multilayer stack may be further deposited to contain a third sublayer. In one embodiment, this third sublayer is another dopant than boron. In a further embodiment, this third sublayer is a dielectric layer. Suitably, such dielectric layer is defined between a pair of first layers of un-doped polysilicon. The intermediate dielectric layer is suitably oxide and is more suitably present in a thickness so that as to allow tunnelling of holes (or electrons). The introduction of such intermediate dielectric layer is deemed suitable to further reduce the risk of dopant migration to the emitter region.

The passivated contact created by the tunnel dielectric and the doped polysilicon layer may be integrated into the solar cell in various positions. Most suitably, in a first embodiment, the passivated contact is applied on the second side of the substrate. In one implementation, the tunnel dielectric is in contact with the bulk of the substrate, which typically has a polarity opposite to that of the doped polysilicon layer. The passivated contact functions then as an emitter region. In another implementation, the substrate has the same polarity of that of the doped polysilicon layer. The passivated contact functions then as a base contact. In further implementation, a conductive layer or region with the same polarity as that of the doped polysilicon layer is present adjacent to the tunnel dielectric. The passivated contact functions then as an emitter contact.

In a second embodiment, the passivated contact is applied on the first side of the substrate. It is then most suitably used as an emitter contact. In principle, it could also be used as an emitter region. However, because the doped polysilicon layer is not or not entirely transparent to light, it is desired that any doped polysilicon at the first side is present in limited areas only. This would significantly reduce the junction area between the emitter and the base (substrate), if the doped polysilicon layer were used as the emitter region.

In a further implementation hereof, the method comprises the steps of: (1) providing a passivation, at least on the first side; (2) locally opening the passivation at least on the first side; (3) applying the tunnel dielectric; (4) providing the doped polysilicon layer in accordance with the invention; (5) applying a masking layer in accordance with a predefined pattern; and (6) etching away the doped polysilicon layer that is not masked. This further implementation makes use of selective etching of the doped polysilicon relative to the passivation, more specifically a passivation comprising a silicon nitride layer. The local opening of the passivation at least on the first side is for instance achieved by laser ablation. In a further implementation, the masking layer is applied by local deposition of a metallic contact, for instance by printed metal paste.

As discussed hereinabove, the solar cell comprises in one further embodiment an electrically conductive layer or region directly on top of the substrate respectively in the substrate adjacent to its surface at the first and/or second side. More particularly this layer or region is separated from the doped polysilicon layer by the tunnel dielectric. It is used for lateral conduction and therein acts particularly as an emitter. This conductive layer or region may be provided in at least two different embodiments: as a conductive region in the substrate, and as another doped polysilicon layer directly onto the surface of the semiconductor substrate, before deposition of the tunnel dielectric.

The provision of a conductive region into the substrate may be carried out, as known to a person skilled in the art, for instance with a diffusion process. The further doped polysilicon layer is suitably deposited as a sequence of alternating first layers of un-doped silicon and second layers of dopant, and subsequent annealing. This doped polysilicon layer present on the substrate is deemed suitable as a source of dopant for the underlying substrate. The anneal step for such further doped polysilicon layer is suitably combined with the anneal step for the doped polysilicon layer applied on top of the tunnel dielectric. In this embodiment, the tunnel dielectric is most suitably a tunnel oxide, which allows its creation by thermal oxidation. The entire stack of polysilicon layers and tunnel oxide may be deposited in a single reactor chamber. Suitably, the further doped polysilicon layer acts as a spreading layer. It is preferably not patterned or at least less extensively than the passivated contact.

In one further suitable embodiment, the doped polysilicon layer is patterned and electrically isolated in lateral directions. This is particularly preferred in case that other contacts, typically towards regions with opposed conductivity type are present adjacent to the doped polysilicon layer. Such a patterning and the—optional—provision of further contacts doped with a dopant of different conductivity type is suitably carried out as a further treatment between the deposition of the multilayer stack and the anneal. This is advantageous from process integration perspective. Moreover, any treatment may be better controlled, i.e. etching of the multilayer stack with bare silicon sublayers and boron sublayers may be more easy than the etching of the doped polysilicon layer.

In one implementation, this treatment involves the selective introduction of a second dopant into the multilayer stack, which second dopant has a polarity opposite to that of the—first—dopant of the second sublayers. The second dopant is suitably introduced into the multilayer stack in a dopant concentration so as to at least compensate, in a first region, the first dopant. As a consequence, the resulting polysilicon layer will be either substantially undoped in this first region, or effectively doped with the second dopant.

In another implementation, the further treatment comprises selectively removing the multilayer stack. Subsequently thereto, conductive regions may be generated into the substrate that has been exposed due to the selective removal of the multilayer stack. This implementation provides an even larger freedom of designing the conductive regions and any contacts thereon. Here, self alignment may occur, with the doped polysilicon layer and/or a protective layer thereon, as a mask.

The anneal of the present invention is suitably carried out at a temperature below 950° C., and preferably in the range of 675-950° C., such as 825-925° C. It is understood to be one of the advantages of the process of the invention, that a low-temperature anneal is feasible, as compared to anneals needed in diffusion or implantation process. Such a low-temperature anneal further reduces the risk of damaging the tunnel dielectric and reduced temperature budget for the other features of the solar cell. The anneal is particularly carried out so as to convert the multilayer stack into a single doped polysilicon layer having a desired doping profile. The higher the anneal temperature and the longer its duration, the more uniform the resulting doping profile. Furthermore, the doping profile (in a direction normal to the substrate surface) can be varied by means of the thicknesses of the sublayers.

The anneal furthermore may have a duration that is short in comparison to the duration of an boron implantation anneal or of a boron diffusion. A suitable period is less than 1 hour, preferably 10-50 minutes, for instance 20-40 minutes. As typical in the field, this period refers to the duration of the anneal at the intended temperature. Warming up and cooling down periods are not included. The anneal is suitably carried out in a different reaction chamber than the deposition of the multilayer stack.

It is not necessary that the anneal is carried out directly after the deposition of the multilayer stack. Intermediate process steps may be carried out, such as for instance the patterning of the doped polysilicon layer, the selective provision of dopant of opposite polarity so as to compensate the boron doping locally, and/or the provision of further dopants into the substrate or other exposed layers.

Preferably, the method of the invention is implemented with a low pressure chemical vapour deposition apparatus comprising a reaction chamber, means to apply a sub-atmospheric pressure in the reaction chamber and a first and a second inlet means for precursor gases into the chamber, which first inlet means is predefined for a silicon precursor gas and which second inlet means is predefined for a dopant precursor gas, which inlet means are provided with valves for controlling the inlet of said silicon precursor gas and said dopant precursor gas. The apparatus further comprises a controller configured for control of the inlet means. According to the invention, the controller is configured so as to arrange first periods in which silicon precursor gas enters the reaction chamber and second periods in which dopant precursor gas enters the reaction chamber. More particularly, the second inlet means comprises a distributor means coupled to a first and a second inlet into the reaction chamber.

The use of such an apparatus has the advantage that the dopant precursor gas, such as diborane, is spread appropriately within the reaction chamber. Therewith, it is ensured that the uniformity over the substrates will be improved. This is particularly a benefit, when the reaction chamber is configured for simultaneous processing of a large number of substrates, for instance 500 or more or even 1000 or more substrates in a single batch. The distances between individual substrates arranged in one or more so-called wafer boats are therein relatively small, preferably at most 8 mm, more preferably at most 5 mm or even smaller such as 2, 3 or 4 mm.

The apparatus is suitably further configured for the generation of a thermal oxide. It is moreover deemed suitable that removal means are present for removal of gases, such as unused precursor gases and any gas remaining after the deposition (reaction). The removal means are suitably configured so that the concentration of such gas is reduced to substantially zero. For instance, use may be made of an inert gas for flushing the reaction chamber. Also the removal means may use vacuum to actively remove gases from the reaction chamber.

The reaction chamber is preferably of the so-called horizontal type, which is the preferred choice for the manufacture of solar cells. However, the invention may alternatively applied in a reaction chamber of a vertical type. The apparatus further contains heating means to obtain a desired operation temperature, as well as moving means for introduction and removal of a wafer boat loaded with substrates into and from the reaction chamber.

### BRIEF INTRODUCTION TO THE FIGURES

These and other aspects of the method and the solar cell of the invention will be further elucidated with reference to the Figures and to the Examples. The Figures are not drawn to scale and purely intended for illustrative purposes. Equal reference numerals in different figures refer to the same or corresponding part. Herein:

FIG. 1A-E shows in diagrammatical cross-sectional views a first embodiment of the method of the invention, and two resulting devices;

FIG. 2A- shows in diagrammatical cross-sectional views a second embodiment of the method of the invention, and a resulting device;

FIG. 3A-B shows in diagrammatical cross-sectional views a third embodiment of the method of the invention, and a resulting device;

FIG. 4 shows in diagrammatical cross-sectional view a fourth embodiment of the invention, a resulting device;

FIGS. 5 and 6 shows in diagrammatical cross-sectional view a fifth and a sixth embodiment of the invention;

FIG. 7 shows a doping profile in a doped polysilicon layer using multi-layer deposited approach, and

Table 1 shows the sheet resistivity and standard deviation of the sheet resisitivity as a function of doping method and substrate distance

### DISCUSSION OF ILLUSTRATED EMBODIMENTS

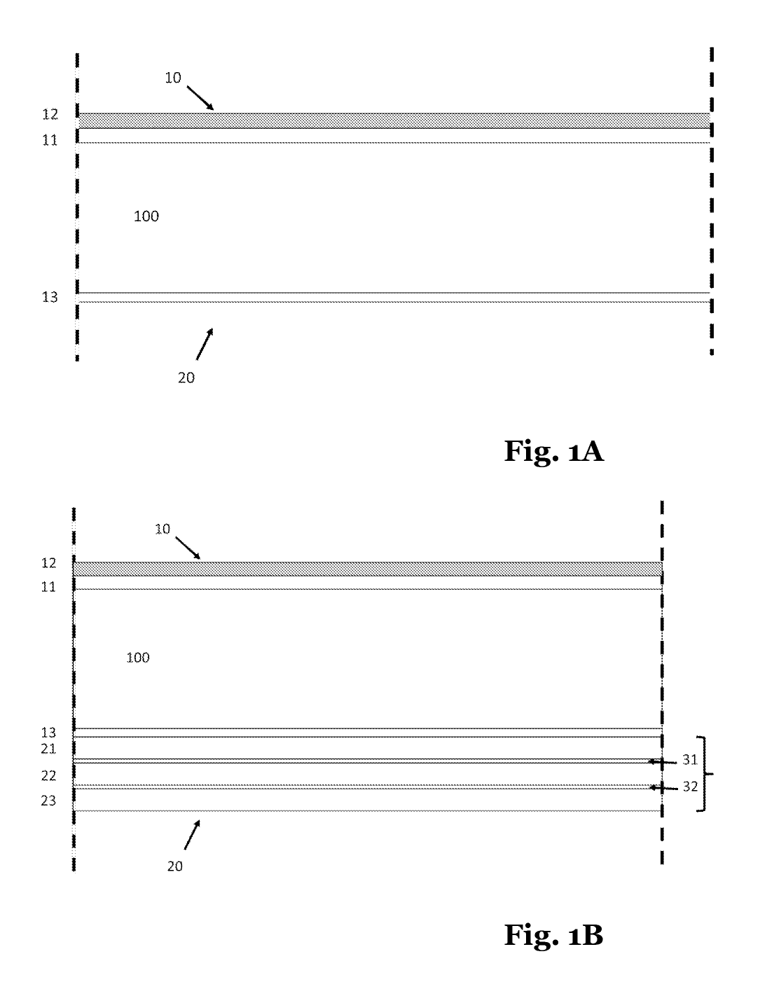

FIG. 1A-D show in cross-sectional views several steps according to a first embodiment of the method of the invention. For all cross-sectional views, the dashed lines on the left and right side of the cross-section indicate that only part of the entire solar cell is shown and not the edges of the cell. FIG. 1A shows the substrate 100, having a first side 10, the front side of the solar cell intended to be the main side receive light, and an opposed second side 20. The substrate is preferably a semiconductor substrate, such as a mono-crystalline silicon substrate. It is however not excluded that another type of substrate is used. While the first side 10 of the substrate is shown to be planar, this is usually not the case, and texturing such as typically applied on the front side of substrates for solar cells may be present.

In this embodiment, the substrate 100 comprises a bulk layer, which is lightly p-type doped, and front surface region 11. This surface region 11 is preferably n-type doped and constitutes the emitter of a solar cell. In this implementation, the doping of the bulk layer 100 and of the front surface layer 11 are of opposed types, i.e. p-type and n-type. In another implementation, the bulk layer 100 and of front surface layer 11 are also opposed type; but exchanged i.e. n-type and p-type. In again another implementation, the doping of the bulk layer 100 is of the same type as the front surface layer 11. Doping levels for these layers are known per se in the field. The substrate is covered at its first side with a passivation 12, which typically includes an oxide layer and an antireflection coating.

The substrate 100 may further be provided at its rear side 20 with a rear surface layer (not shown in FIG. 1). When present, it is highly doped, as known per se to the skilled person. The rear surface layer is a region within the substrate 100 that is doped with either n- or p-type. Suitably, in the present embodiment, the surface layer would have the same polarity as the substrate 100, thus p-type.

FIG. 1A furthermore shows the presence of a dielectric 13 at the second side 20. According to a preferred embodiment, the insulating layer 13 is provided in a thickness suitable for functioning as a tunnelling dielectric. This implies a thickness of generally up to about 3 nm. For a tunnelling dielectric with a thickness of less than 3 nm, the tunnelling current through the dielectric is strongly dependent on the thickness. Therefore the thickness needs to be well controlled. A too thin dielectric may not passivated the silicon well enough, while a too thick dielectric cannot conduct the required solar cell current. Techniques for deposition of a tunnel dielectric are known per se. For instance, the tunnel dielectric 13 may be deposited by means of chemical oxidation, thermal oxidation or by atomic layer deposition. Suitably, the insulating layer 13 is an oxide, but this is not deemed essential.

FIG. 1B shows the result of the deposition of a multilayer stack. Herein, silicon sublayers 21, 22, 23, and dopant sublayers 31, 32 are deposited alternatingly. The dopant is preferably boron, though other dopants are not excluded. The sublayers are suitably applied in substantially pure form, i.e. pure silicon and pure dopant. However, they may also be applied as mixtures, with one element being predominantly present. In the embodiment of FIG. 1B, two dopant sublayers 31, 32 are shown which are sandwiched between silicon sublayers 21, 22, 23. It is deemed preferable that the stack of sublayers forming a doped polysilicon layer (stack) 30 has a silicon sublayer 21 as its bottom layer, i.e. at the interface with the underlying tunnel dielectric 13 and a silicon layer 23 as its top layer, i.e. at the second side 20. The number of sublayers is however open to further design and may depend on the application. Suitably, the number of dopant sublayers 31, 32 ranges from 1 to 100. Preferably, the number of dopant sublayers is at least 2, which may provide a better distribution of the dopant in the doped polysilicon layer stack 30. Suitably, the number of sublayers is in the range of 2-80 or 5-50. The upper limit is herein dependent on the total thickness of the doped polysilicon layer stack 30 as well as the desired dopant concentration and the available processing time. The multilayer stack remains as such, it has been annealed.

Preferably, the dopant sublayers 31, 32 are provided in the form of relatively thin sublayers, for instance with a thickness in the range of 0.1-5 nm, or even 0.1-2 nm. Good results have been found with such thin layers in terms of homogeneity as well as dopant concentration. It has been observed by microscopical analysis (i.e. TEM, SEM or the like) that the initially grown dopant sublayers possess a very regular microstructure. It is only after a subsequent anneal that the dopant sublayers 31, 32 and the silicon layers 21-23 merge, i.e. that inter-diffusion occurs. One of the benefits hereof for the invention is that the extent of inter-diffusion may be controlled by the annealing budget (i.e. temperature and duration). A further advantage of the encapsulation of the dopant sublayers 31, 32 within silicon layers 21-23 is that further processing may be carried out prior to the anneal. The well-known processing properties of polysilicon can thus be exploited without any risk of leakage of dopant and any optimal contamination of other layers. This allows to also deposit the tunnelling dielectric by thermal oxidation right before the deposition of the polysilicon, a method deemed very favourable for good tunnel dielectric thickness control.

In the present embodiment, the multilayer stack of this preferred embodiment is deposited in an LPCVD apparatus. Suitably, the substrates are arranged in this apparatus at a mutually narrow spacing, for instance less than 8 mm, preferably less than 5 mm, more preferably less than 3 mm. The spacing occurs while the substrates are arranged in a holder, also known as a wafer boat. The use of a small spacing allows significant through-put enhancement of the LPCVD apparatus, while the doping characteristics of the layer are significantly enhanced. Surprisingly, the uniformity of the doping characteristics across the substrate is improved with reduced spacing between the substrates. Moreover the use of the LPCVD apparatus applying a multilayer stack also allows a thermally grown tunnel oxide prior in the same LPCVD deposition apparatus prior to depositing the multilayer stack. This allows very good thickness control of the tunnel dielectric, which is required to allow good operation of the solar cell in which hole currents through the tunnel dielectric are required.

It is observed for clarity that the structure of silicon depends on its deposition temperature. At a deposition temperature of 500° C., no grain development occurs and the silicon remains amorphous. With increasing temperatures, the grains may grow. Above 600° C., the layers are deemed to be polysilicon, i.e. a crystalline silicon layer made up of a plurality of individual grains or crystal domains with differing orientations. At higher growth temperatures, the crystal domains increase in size. Furthermore, an anneal may give rise to re-crystallisation, resulting in enhanced crystallinity of the silicon layer, also if the layer was deposited as predominantly amorphous. However, the formation and growth of crystallites just below the phase transition appears flexible and highly dependent on pressure and other deposition conditions. It is for instance known that the phase transition temperature is lower in LPCVD and low growth rates. According to the present invention, it is preferred that the dopant sublayers 31, 32 are present between silicon layers that are at least partially crystalline. Deposition temperatures of 530-600° C., preferably combined with sub-atmospheric pressures are preferred. This is at a temperature slightly below what the said phase transition temperature. The provision of an amorphous film is deemed beneficial because of its planar surface enabling the subsequent deposition of a regular dopant film, particularly a boron film. However, due to the thin-film arrangement of the polysilicon, and perhaps the impact of the boron film, formation and growth of crystallites is believed to occur in the course of the deposition process. The exact mechanism is not known but this may be an explanation for the unexpected good properties of the resulting layer stack in terms of diffusion of the dopant. The polysilicon character of the silicon sublayers 21-23 is deemed relevant for the uniformity of the layer deposition between substrates.

Furthermore, in accordance with the embodiment of the invention, the deposition of the sublayers occurs in a single deposition chamber, wherein the temperature and pressure are suitably controlled, and may be kept constant during the entire deposition process. Preferably, deposition temperature is the same for both the silicon sublayers and the dopant sublayers. It will be understood that this deposition of preferably all sublayers of the multilayer stack 30 in a single deposition chamber is beneficial for efficiency and layer quality. It has been found suitable that the formation of the dopant sublayers 31, 32 and the (poly)silicon sublayers 21-23 occurs separately. Thus, in the preferred embodiment, the reactor chamber is emptied from silicon precursor gases (such as silane) prior to the introduction of dopant precursors (such as diborane). After the formation of the dopant sublayer, the reactor chamber may again be emptied to continue with the deposition of the subsequent silicon sublayer. This emptying of the reactor chamber after the deposition of the dopant sublayer does not appear essential to the invention.

While the use of a single deposition chamber for all sublayers is the most simple and most efficient solution, it is evidently not excluded that use is made of coupled deposition chambers (i.e. with constant gas compositions, and a system for moving the substrates) and/or that the doped polysilicon stack 20 is deposited in two, three, four or five sequences (in fact in a limited number of sequences, for instance from 2-8). The use of more than one sequence appears beneficial in case that an intermediate processing step is carried out (such as patterned removal of the doped layer stack 30), or that another dopant gas (of opposite polarity) would be applied in a later step, or that for reasons of optimization, the stack is deposited at a series of different temperatures. Particularly, a first “substack” could be deposited at a higher deposition temperature, for instance 630° C., to ensure a high degree of poly-crystallinity, whereas a second “substack” is then deposited at a lower deposition temperature, for instance 570° C., allowing growth of thinner dopant layers. If desired, a third “substack” could be deposited again at a higher deposition temperature. Each of such substacks is foreseen to comprise a plurality of alternating sublayers, although it is strictly feasible that the first and the second substack merely contain a single polysilicon layer.

Furthermore, the thickness of the silicon sublayers 21-23 and the dopant sublayers 31, 32 is suitably uniform with the stack, i.e. at least substantially all silicon sublayers 21-23 are deposited in a first thickness and at least substantially all dopant sublayers 31-32 have a second thickness. Variations in thickness may however be envisaged, depending on the intended application. In this FIG. 1A-1E, the intended application is use as rear, back surface field or rear emitter contact. In those cases, a uniform distribution of dopant in a ‘vertical’ direction (perpendicular to the second side 20) is desired. Variations in thickness of sublayers are then not deemed beneficial, with possible exception for bottom and top sublayers 21, 23.

It is observed that the use of chemical vapour deposition will usually result in deposition of layers at both sides 10, 20 of a substrate. In the present FIG. 1B, deposition on the second side 20 is shown. Thus, in this embodiment, the deposited layer stack on the first side is removed, such as by etching any stack on the second side 10, while simultaneously protecting the second side and/or by means of single sides processing, for instance in single sided etch tool.

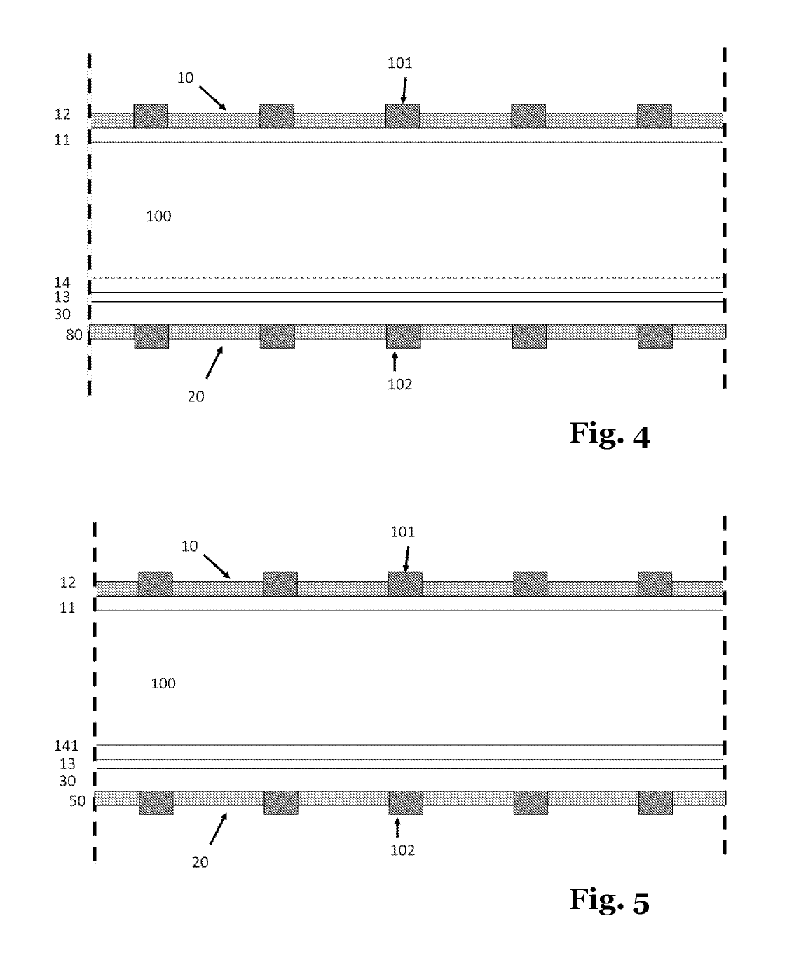

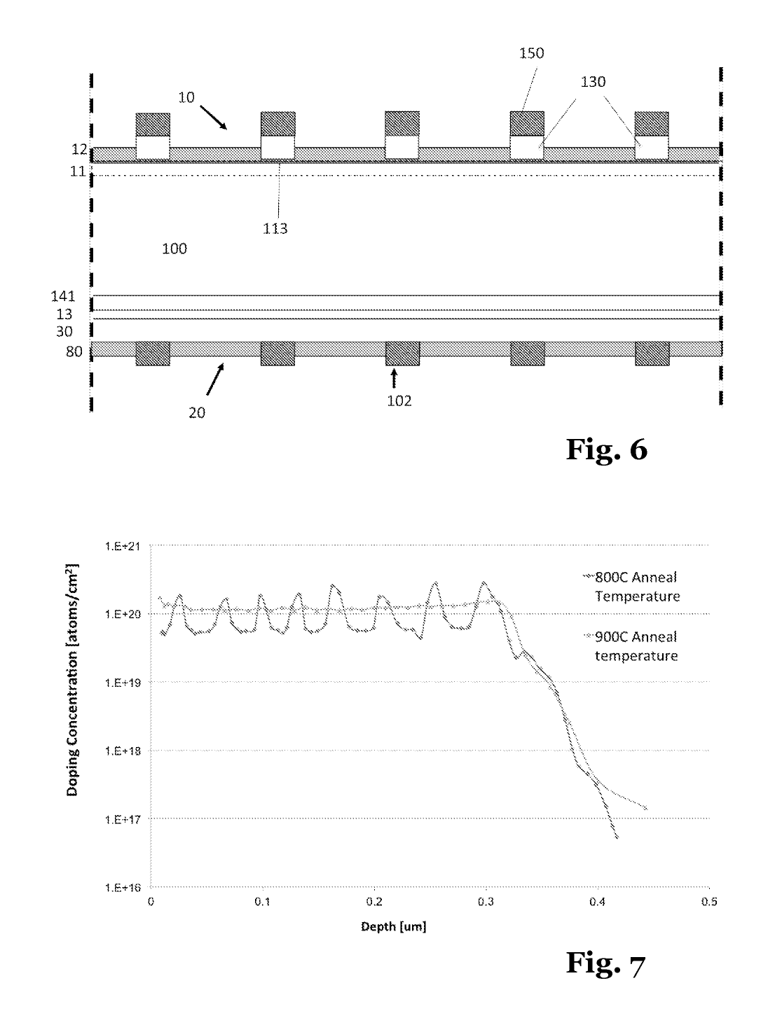

FIG. 1C shows the substrate after the anneal step—i.e. the final step of creation of the doped polysilicon layer 30. As shown in this FIG. 1C, the multilayer stack is transformed into a single doped polysilicon layer 30. As will be explained in more detail with reference to FIGS. 6 and 7, the final microstructure depends on the duration and temperature of the anneal. In some embodiments, the dopant sublayers 31, 32 may still be identifiable in the resulting device, particularly by means of analysis of the dopant concentration as a function of depth (location in vertical direction). Particularly, a doping profile may be obtained with maximum concentrations corresponding to the dopant sublayers 31, 32 and minimum concentrations within the polysilicon sublayers 21-23. In other embodiments, the dopant sublayers 31, 32 and at least some of the silicon sublayers 21-23 may be fully mixed, resulting in a doping profile that is substantially flat.

It has been found that the provision of the boron doped polysilicon layer as a multilayer stack of alternating deposited boron and silicon layers lowers the required temperature budget of the anneal to diffuse the boron through the entire polysilicon layer. This is deemed very important to prevent the effect of boron penetrating the tunnel dielectric and thus to maintain the passivated properties of the boron doped polysilicon passivated contact. Another advantage of the multilayer stack of alternating deposited boron and silicon layers is that the potential out-diffusion can be controlled. In case the sequence of the depositing a multilayer stack ends with a silicon layer, potential out-diffusion of boron into the anneal furnace can be limited significantly. Boron out-diffusion can negatively influence the other parts of the solar cell by counter doping other n-type doped areas. In case the sequence of the depositing a multilayer stack ends with a boron layer, the out-diffusion mechanism can be used to dope other parts of the solar cell.

FIG. 1D shows the substrate after the final step of creating a solar cell, in which a plurality of metal contacts 101 is applied on the first side, front of the solar cell, while one or more contacts 102 are applied at the second side, on top of the doped polysilicon layer stack 30. The metal contacts 101 and 102 are herein shown as a patterned layer. This may be achieved either by screen printing or by deposition and subsequent etching or by local deposition, for instance through a mask, such as in a plating process. The metal of the metal contact 101 is preferably chosen such that it forms a good contact to the bulk 100 of the solar cell, while the metal contact 102 is preferably chosen to enable formation of a good contact to the underlying polysilicon (see FIG. 1D). Suitable materials may include tungsten (W), titanium (Ti), nickel (Ni), silver (Ag) or aluminium (Al) or copper (Cu). While reference is made to metal contact, it is not excluded that such metal contact is deposited as a metal-containing compound. It will be understood that the definition of a metal contact is beneficial, but still optional. It is observed for clarity, that the further processing into a solar cell involves the provision of cell passivation and metallisation, generally also referred to the ‘back end’ as opposed to the ‘front end’ of definition of the device and its contacts into and on the substrate. The term ‘solar cell’ is thus used in context of the application to refer to the completed solar cell that is ready for shipment and/or assembly.

FIG. 1E shows the solar cell that is provided with an alternative cell passivation. Herein, the doped polysilicon layer 30 is covered with a transparent conducting layer 15. A plurality of metal contacts 102 is provided on top of the transparent conducting layer 15. The transparent conductive layer for instance contains indium tin oxide, but may contain any other transparent and electrically conducting material as known to the skilled person. The solar cell thus obtained is conceived where the first side 10 is the main side for receiving light. Furthermore, the second side 20 will also collect light, hereby creating a so-called bi-facial solar cell. Since the second side 20 is provided with a plurality of emitter contacts 102, the light coming from the rear side is not blocked by the metal.

Another option for the bi-facial cell is that the layer 15 is a dielectric, such as for instance a silicon-nitride or silicon-Oxide or combinations of dielectrics. In such case the rear contacts 102 will extend through the dielectric to form contacts directly to the silicon layer 30. This construction allows also screen printing techniques, where metal pastes penetrate through the dielectric during a belt-furnace firing step. The silicon layer 30 would need to be sufficiently thick so that the screen printed metal will not fire through the silicon layer and damage the underlaying tunnel dielectric.

### Second Embodiment

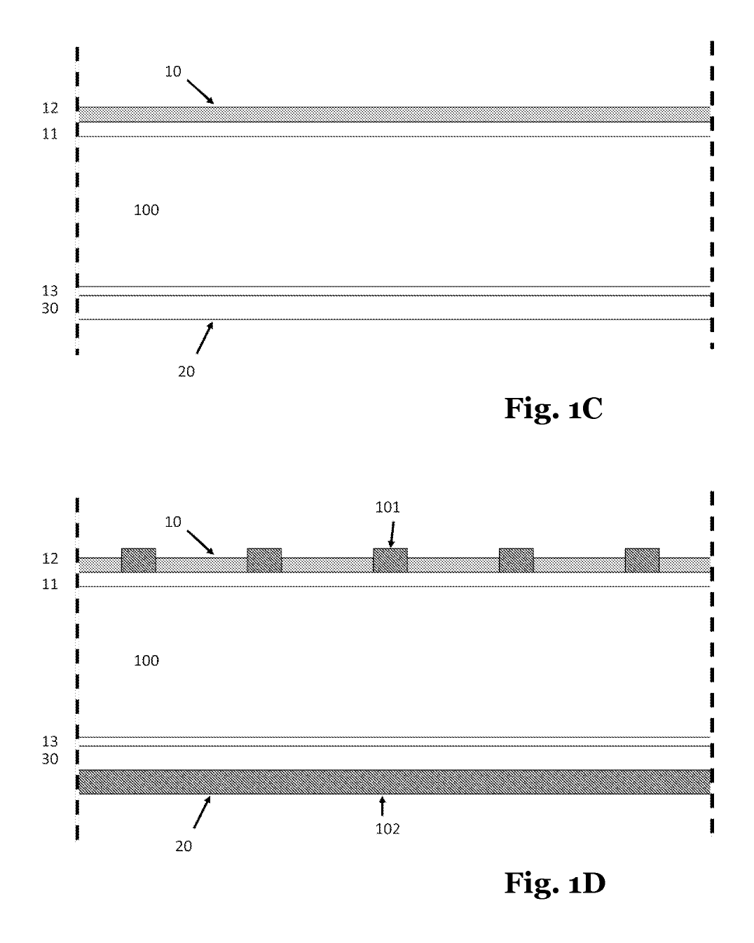

FIG. 2A shows an intermediate step in the solar cell process sequence. The view is a diagrammatical cross-sectional view, where the vertically dotted lines represent a cut-out of the entire solar cell. For sake of clarity, the device is shown in a semi-manufactured form, so as to indicate the way the solar cell processing steps are defining the solar cell. At the main, first side 10—intended for primary reception of sunlight, the device has a doped region 11 and an anti-reflective layer 12. The first side 10 of the substrate 100 may be textured to increase light reception. In this embodiment, the substrate 100 is provided with a plurality of doped polysilicon layer portions 30 at the second side 20. The doped polysilicon layer portions are covered by a protective layer 50. A tunnel dielectric 13 is present between the doped polysilicon layer portions 30 and the substrate 100. The layer portions 30 form an interdigitated set of emitters. Optionally the doped polysilicon layer 30 could be applied also on the first side 10 suitably instead of the doped region 11. As in the first embodiment, the layer stack 30 comprises silicon and boron sub-layers (not indicated with a reference numeral individually) and dopant sublayers which are not shown in this FIG. 2A. The polysilicon contacts are typically connected to each other to allow efficient connection to the solar module, which is not shown in the picture, for instance through a laterally extending portion of the polysilicon layer 30.

The protective layer 50 can be deposited uniformly using for instance a PECVD apparatus and subsequently be patterned. Alternatively, the protective layer 50 can be applied and defined as a mask using for instance screen printing. The protective layer 50 can contain one or more materials such as silicon nitride, silicon oxide, tantalum oxide, titanium nitride, without desiring to limit the protecting layer to a nitride. The protecting layer 50 has been patterned in accordance with a predefined pattern on the second side 20, protecting the emitter contacts 30. The patterning definition of the protecting layer can be applied by for instance screen printing. As shown in this FIG. 2B, the protecting layer is also serving as an etch mask. Chemical etching is used to locally remove the polysilicon layer. Alternatively, the doped polysilicon layer stack 30 can be locally removed up to the underlying substrate 100 by an etching paste or by laser ablation.

FIGS. 2A and 2B further show the presence of recesses 70 between the interdigitated doped polysilicon layers 30 that extend to or into the substrate 100, or optionally to the tunnel dielectric 13. These recesses 70 may be created by local laser ablation or local etching. Local etching may be also achieved by an etching paste which is applied at the predefined locations 70 to etch away the polysilicon locally. In FIGS. 2A and 2B, the recesses 70 are shown as recesses of only the polysilicon layer 30, but the process may be embodied in a way that the recess is much deeper into the substrate 100. Such deeper recess can be advantageous, since it results in a larger physical separation between the polysilicon contacts 30 and—electrically conductive—bulk regions 40. Effectively, the polysilicon contacts 30 are in this embodiment emitter contacts, whereas the bulk regions 40 constitute part of a back surface field, for instance. Thus, the dopants in the contact regions 30 and the bulk regions 40 are of opposite polarity.

The bulk regions, 40, are suitably n-type doped, and more preferably phosphorous doped. Such doping may be provided by various methods for instance with tube diffusion, ion implantation, doped glass deposition, by screen printing inks or by another doped polysilicon deposition. After these doping methods subsequently they may have to be annealed using an anneal furnace, with a high temperature step during which the phosphorous dopants are diffused into the bulk. During this step, the protective layer 50 prevents phosphorous dopant diffusion into the boron doped polysilicon. This anneal step may also be used for converting the multilayer stack into the polysilicon doped layer 30.

After opening the polysilicon layer, the bulk regions 40 can be formed. Herein, the protective layer 50 serves to protect the polysilicon emitter 30 from the contamination with the dopant of the bulk regions 40, preferably phosphorus. In one suitable implementation, wherein the phosphorous is applied in a diffusion process, the phosphorous diffusion at the same time serves as the anneal step for the polysilicon layer 30. Alternatively, the protective layer serves as an implantation mask, protecting the emitter regions 30 from being implanted. Subsequently, a thermal anneal is carried out to simultaneously anneal the polysilicon emitter 30 as well as the driving in the implanted phosphorus doping and remove the implantation damage.

FIG. 2C shows the final solar cell device after further processing into a passivated solar cell and definition of metal contacts. After cleaning the device, for instance in a wet treatment, a passivation layer 80 is formed at the rear side 20 of the solar cell, followed by metal contact formation 101 and 102. The emitter contacts 102 are connected to the polysilicon regions and the bulk contacts 101 to the bulk diffusions. There is a passivation layer 80 that passivates the bulk regions and also serves as a hydrogen source for the firing process in case screen printed contacts are fired in a belt furnace. The passivation layer 80 is deposited at the rear of the solar cell in a PECVD apparatus and will contain silicon nitride and optionally also of silicon oxide. As an option, the layer 80 encompasses of the protective layer 50, i.e. the protective layer 50 is not removed prior to deposition of the passivation layer 80.

### Third Embodiment

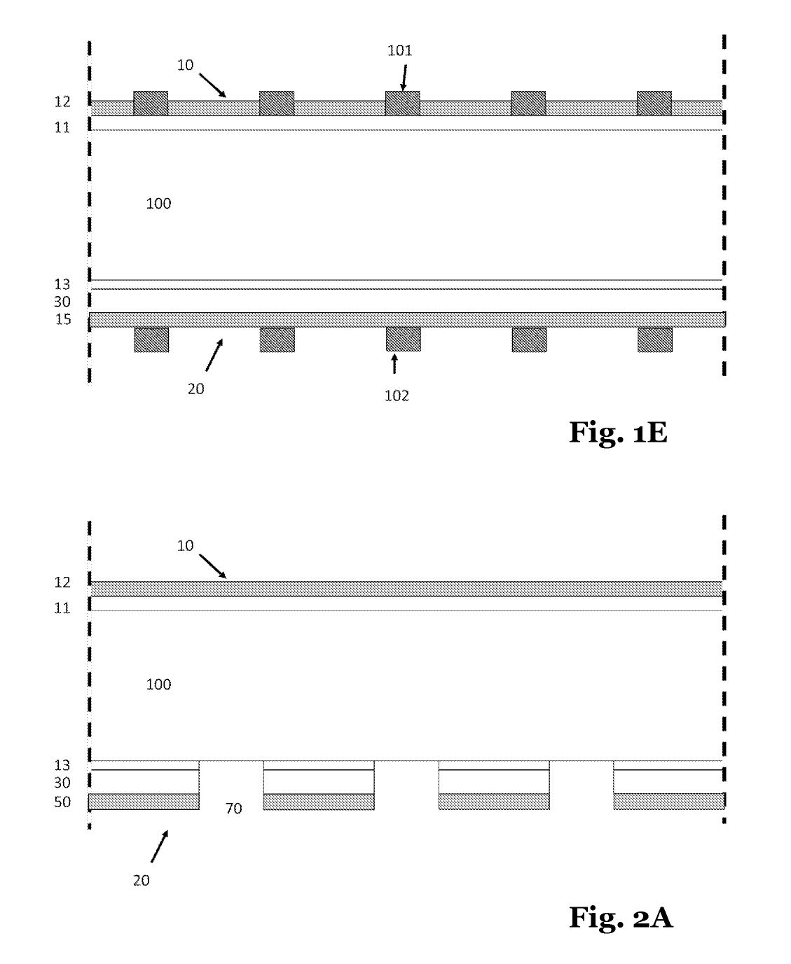

FIG. 3A shows another way of creating an inter-digitated device. In this example the boron-doped polysilicon is locally overcompensated by phosphorous. This can be achieved for instance by using a protective mask 50, and subsequently deposition of phosphorous glass or by ion implantation. A subsequent anneal drives the dopant into the polysilicon layer stack 30, locally creating phosphorous n-type regions 60. The amount of the dopant is therein chosen such that the dopant from the dopant layer 60 overcompensates the dopant of opposite polarity in the polysilicon layer 30. Thus, in the preferred example of a phosphosilicate glass (PSG) as dopant layer 60 with boron sublayers in the deposited stack 30, the amount of phosphorous dopant into the polysilicon layer 30 is such that the polysilicon layer will become locally N-type (i.e. phosphorous) doped rather than P-type (i.e. boron). Again, in this embodiment, the anneal for the polysilicon layer 30 may be combined with the anneal for the phosphorous n-type regions 60.

In FIG. 3B the final solar cell of this third embodiment is shown. Here a series of contacts 101, 102—typically arranged inter-digitatedly—is formed, the contacts 101 being bulk or back surface field (BSF) contacts, and the second contacts 102 being contacts to the emitter polysilicon layer. There is a passivation layer 80 deposited on the polysilicon layer that protects the layer from oxidation. The passivation layer 80 contains in this embodiment silicon nitride and optionally also of silicon oxide and may contain hydrogen for better passivation of the solar cell after firing the metallization paste. As an option the passivation layer 80 still encompasses the protective layer 50. Layer 80 is deemed not essential for the operation of the solar cell and can thus be optionally left out.

### Fourth Embodiment

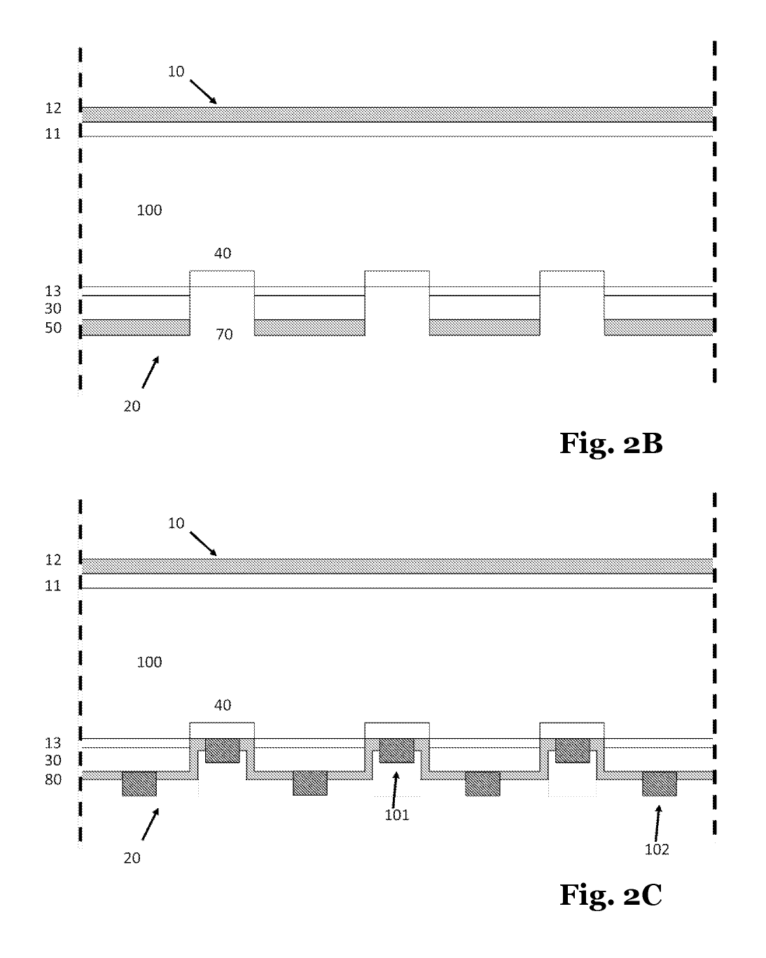

FIG. 4 shows again a further embodiment in cross-sectional view. According to the embodiment shown in FIG. 4, a first boron doped region 14 is provided before the tunnel dielectric and the second polysilicon layer 30. The region 14 is herein present below the tunnel dielectric layer 13. The doped polysilicon layer 30 is present above the tunnel dielectric 13. The region 14 serves in this embodiment for lateral conduction of the emitter, i.e. as a spreading layer. The doped polysilicon layer 30, which is again made by a multilayer as described earlier, serves for interconnecting the metal contact 102 with the conduction region. The regions 14, tunnel dielectric 13 and polysilicon layer 30 are formed in a single sequence in a single process tube, thereby simplifying the whole emitter definition. Alternatively, the first doped region 14 is formed separately from the tunnel dielectric 13 and doped polysilicon layer 30. The first doped region 14 can be formed by different doping methods like boron diffusion, APCVD or ion implantation. This embodiment allows thinner doped polysilicon layers which is deemed beneficial for the through-put time, particularly when using an LPCVD apparatus for the polysilicon deposition. Furthermore, this embodiment results in lower light absorption due to decreased thickness, which may even be more important.

### Fifth Embodiment

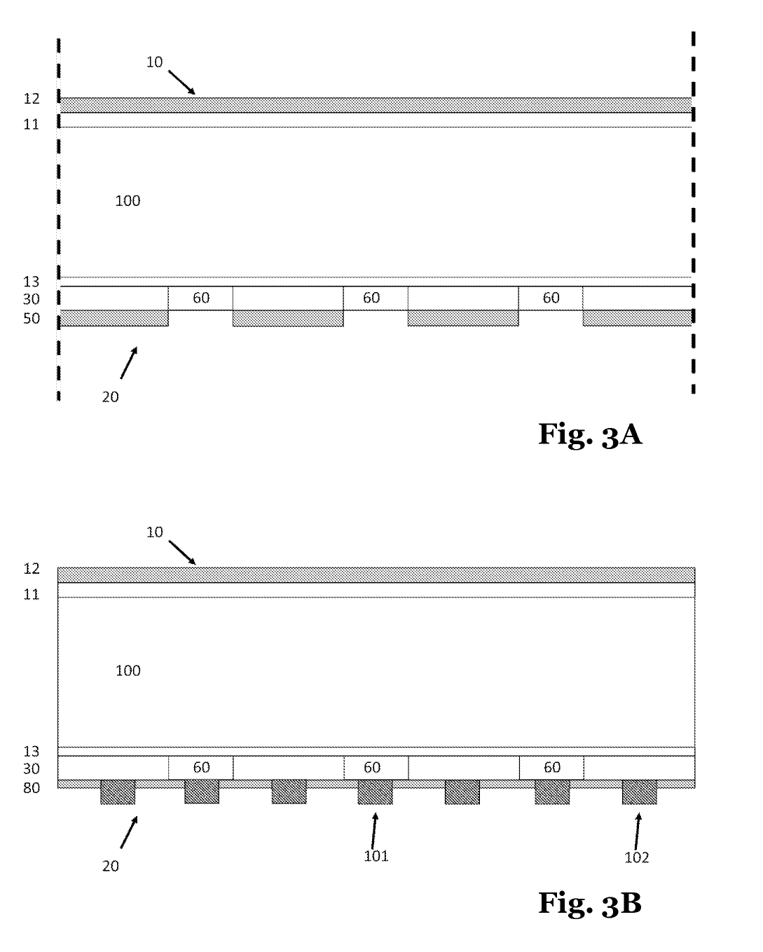

FIG. 5 shows in cross-sectional view a fifth embodiment, which is similar to the fourth embodiment. In this embodiment, the conductive region 14 in the substrate 100 has been replaced by a further doped polysilicon layer 141 defined directly on top of the substrate 100. This further doped polysilicon layer 141 may be deposited in the same manner as the other doped polysilicon layer 30, but that is not strictly necessary. In fact, the risk of diffusion through the tunnel dielectric 13 will be less big for the boron dopant in the further doped polysilicon layer 141. Still, the alternate deposition is deemed beneficial, for instance to obtain a very well defined interface between the substrate 100 and the polysilicon layer 141, which defines the junction. Moreover, by starting the alternate deposition with a substantially undoped silicon layer, an region with lower doping level may be created—further dependent on the anneal conditions. This creates a substantially intrinsic layer between the p- and the n-regions. It is herein preferred that the entire layer stack of further doped polysilicon layer 141, tunnel dielectric 13 and doped polysilicon layer 30 is deposited in a single reaction chamber in an LPCVD apparatus.

### Sixth Embodiment

FIG. 6 shows in cross-sectional view a sixth embodiment. Herein, a passivated contact 130 is applied to the first side 10 of the substrate 100. In the embodiment shown in FIG. 6, this passivated contact is additional to the passivated contacts 30 present on the second side 20. More particularly, the embodiment of FIG. 6 includes all features of the fifth embodiment of FIG. 5. However, this is not essential. The passivated contacts 130 on the first side 10 may for instance be applied to the bifacial cell structure shown in FIG. 1E.

The manufacture of the passivated contacts 130 on the first side 10 suitably starts after finalization of the manufacture on the second side, with the exception of the metal contacts 102. The shown cell structure is prepared by locally opening the passivation 12, for instance using laser ablation or laser etching. The opening of the passivation 12 is carried out in a manner so as to expose the first region 11 in the substrate 100. Then, the substrate is brought into an LPCVD reactor, to grow a tunnel oxide 113, and a multi-stack 30 of alternatingly deposited silicon sublayers and dopant sublayers. This structure is thereafter annealed to form the doped polysilicon layer 130. Suitably, this anneal is also used for the annealing of any other polysilicon layer 30 present. At this stage, the polysilicon layer 130 will cover the entire solar cell, both at the first side 10 and at the second side 20. Then a masking pattern is 150 applied, and the doped polysilicon layer 130 is etched away relative to the underlying passivations 12, 80. Most suitably, this masking pattern constitutes already the metal contacts on the first side 10. However, this is not deemed essential. While the polysilicon layers 30, 130 may both contain boron as a dopant, this is not strictly necessary. One of both could contain phosphorus dopant.

### EXAMPLES

Preliminary results were carried out with test structures having a configuration as shown in FIGS. 1C and 1D. Use was made of a monocrystalline silicon substrate, which was n-type doped in a manner conventional to the skilled person. A plurality of substrates was provided into the reaction chamber of an LPCVD apparatus. The substrates were then processed in accordance with the invention. A tunnel dielectric was applied with a thickness of 1.5 nm, by thermal oxidation. Thereafter, a multilayer stack of silicon layers and boron dopant layers was applied. The multilayer stack started and finished with a silicon layer. The total number of boron dopant layers was 9. The total thickness of the multilayer stack was approximately 400 nm, which was equally divided over the 10 polysilicon layers. The boron dopant layers were comparatively thin. No protection was applied, so that the multilayer stack was grown on both sides of the silicon substrate in identical manner Subsequently, an anneal was carried out.

FIG. 7 shows the doping profile obtained using Electrochemical Capacity Voltammetry of the resulting substrates for two different anneals. A first substrate was given an anneal at a temperature of 800° C. for 30 minutes. A second substrate was given an anneal at 900° C. for 30 minutes. The first and second substrates had been prepared in the same manner. The location of the polysilicon layer, the tunnel dielectric and the bulk silicon substrate are indicated in FIG. 7 for sake of ease of understanding. It is clearly visible that the dopant concentration in the polysilicon layer is much higher than either in the tunnel oxide or in the bulk silicon. In fact, the dopant concentration in the polysilicon layer stack varies between 4·10¹⁹ and 2·10²⁰ (atoms/cm³). It is about 1·10¹⁹ in the tunnel oxide and drops down to 10¹⁷ at approximately 150 nm from the interface with the tunnel oxide. This is independent of the anneal temperature. This seems an indication that the improved stability is not merely the result of a lower temperature budget, but also of a different microstructure.

The doping profile of the first substrate, that has seen an anneal temperature of 800° C., comprises a series of peaks and valleys with respect to the dopant concentration. The dopant peaks correspond to the locations of the initially deposited boron dopant layers. The slope of the peaks is continuous. This demonstrates that the boron dopant sublayer and the polysilicon layer have merged into a single layer in the course of the anneal. It is furthermore apparent that the dopant peaks all have substantially the same height. This implies that substantially no boron migration has occurred from the top and middle of the polysilicon layer towards the tunnel oxide.

The doping profile of the second substrate, which has seen an anneal temperature of 900° C., is nearly flat. It appears that the dopant concentration close to the tunnel oxide is somewhat higher, but the variation is less than a factor of 2. Careful review further demonstrates that the dopant concentration at the locations where dopant sublayers were deposited is still slightly higher than in the neighbouring silicon sublayers.

Table 1 includes data from subsequent experiments. Herein, a comparison was made between boron doped polysilicon layers that were deposited either by continuously doping or by the alternating provision of polysilicon sublayers and boron sublayers. The continuous doping was applied by adding the diborane precursor (B2H6) in a concentration of 3% to the silane precursor. Furthermore, the experiment was repeated with different spacing between individual substrates, more precisely 2, 4 and 8 mm. The table indicates the average sheet resistance R_{s,av} (in Ω/square) and the standard deviation (SD), in Ω/square, after anneal. This resistance was measured with a four-point probe for 7×7 points on a single substrate.

| | 8 mm spacing | | 4 mm spacing | | 2 mm spacing | |
|---|---|---|---|---|---|---|
| | R_{x, av} | SD | R_{s, av} | SD | R_{s, av} | SD |
| Comparison | 143 | 22 | 200 | 50 | 321 | 144 |
| Invention | 132 | 9 | 124 | 7.1 | 119 | 3.7 |

It is apparent from these data that the average sheet resistance is clearly lower in the invention than in the prior art. This is an immediate advantage. Moreover, and even more importantly, the standard deviation is significantly reduced to levels below 10 Ω/square. This is clearly an excellent result that shows that the method is feasible in the industrial production of solar cells. It furthermore turns out that the average sheet resistance and the standard deviation both decrease further when reducing the spacing between the substrates. This is highly surprising, since, in the comparative example, the reverse trend is visible: higher sheet resistance and higher standard deviation with a decrease in spacing.

In summary, the invention provides a new process for deposition of a doped polysilicon layer. In accordance with the invention, the doped polysilicon layer is formed by deposition of a multilayer stack of first sublayers of silicon and second sublayers of dopant in alternation, and subsequent annealing. This is particularly suitably for the formation of a p-type doped, particularly boron-doped polysilicon layer. The concentration of boron doping is herein sufficiently high, in accordance what is widely known as highly doped silicon with a sufficiently low resistance to be useful as an electrically conductive material. This is a doping concentration clearly above the low doping levels that are typically applied in bulk substrate. The multilayer stack comprises a plurality of first and second sublayers, for instance a stack of 5-50 sublayers of each. The first sublayers have a larger thickness than the second sublayers, but are still of limited thickness, suitably less than 50 nm and preferably even less than 10 nm. The resulting layer stack, which may upon annealing is transformed into a single doped polysilicon layer, allows a uniform doping without risk of significant migration of the dopant, i.e. boron into underlying tunnel dielectric, thereby significantly improving passivation of the underlaying substrate. The doped polysilicon layer stack, also referred to as a multilayer stack, and the resulting doped polysilicon layer—in which sublayers still may be distinguished—is for instance suitable for use as an emitter contact or an emitter spreading layer in a solar cell. However, alternative application is not excluded.

In one suitable embodiment, the multilayer stack is deposited in an LPCVD apparatus in which the substrates are spaced less than 8 mm, preferably less than 5 mm, more preferably less than 3 mm. This allows significant through-put enhancement of the LPCVD apparatus, while the doping characteristics of the layer are significantly enhanced. Moreover the use of the LPCVD apparatus applying a multilayer stack also allows to thermally grow a tunnel dielectric prior in the same LPCVD deposition apparatus prior to depositing the multilayer stack. This allows very good thickness control of the tunnel dielectric, which is required to allow good operation of the solar cell in which hole currents through the tunnel dielectric are required.

According to a first aspect, the invention relates to a method of a manufacturing a solar cell, comprising the steps of: (1) providing a semiconductor substrate with a first and a second side, which first side is intended as main side for receiving light; (2) providing a tunnel dielectric on at least one side of the substrate, (3) providing a layer of doped polysilicon onto the substrate, separated from the substrate by the tunnel dielectric, and (4) further processing of the substrate into a solar cell. Herein the provision of the doped polysilicon layer comprises depositing, by means of Low Pressure Chemical Vapour Deposition (LPCVD), a multilayer stack of first sub-layers and second dopant sub-layers in alternation, and subsequent annealing of the multilayer stack into the doped polysilicon layer, which first sublayers predominantly contain silicon and which second dopant sublayers contain boron.

According to a second aspect that can be combined with the preceding aspect, the multilayer stack comprises 2-200, preferably 5-100 dopant sub-layers.

According to a third aspect that can be combined with any of the preceding aspects, the alternating deposition of first and second sublayers occurs within a single reaction chamber through variation of injection of precursor gases into the reaction chamber.

In a preferred embodiment of the third aspect, silicon precursor gas is introduced into the reaction chamber in first periods and dopant precursor gas is introduced in second periods, wherein the second periods are shorter than the first periods, preferably at most 10% of the first periods.

In a further embodiment thereof, the introduction of silicon precursor gas is discontinued during the second periods, and wherein the reaction chamber is emptied, at least substantially from silicon precursor gas prior to the introduction of dopant precursor gas.

In fourth aspect that can be combined with any of the preceding aspects, a single deposition process is carried out for a batch of semiconductor substrates, wherein adjacent semiconductor substrates are arranged at a spacing of at most 8 mm, more preferably at most 5 mm.

In a fifth aspect that can be combined with any of the preceding aspects, the deposition of the first and the second sublayers occurs at a temperature in the range of 500-700° C., preferably 550-600° C. In a preferred implementation thereof, the deposition occurs at a temperature at which the first sub-layers are initially deposited in amorphous form and at which formation and growth of crystallites proceeds.

In a sixth aspect that can be combined with any of the preceding aspects, the anneal temperature is below 950° C., preferably in the range of 600-925° C., preferably in the range of 800-925° C. In a preferred implementation thereof, the anneal has a duration of less than 1 hour, preferably 10-50 minutes, for instance 15-30 minutes.

In a seventh aspect that can be combined with any of the preceding aspects, the tunnel dielectric is a thermally grown oxide, that is grown in the same reaction chamber wherein the multilayer stack of the doped polysilicon is deposited.

In an eighth aspect, which can be combined with any of the first six aspects, the tunnel dielectric is grown prior to entering the LPCVD apparatus. For instance, the tunnel dielectric is AlOx made in an Atomic Layer Deposition apparatus.

In a ninth aspect that can be combined with any preceding aspect, the doped polysilicon layer is provided on the second side of the substrate. In a first embodiment, an electrically conductive region is applied into the substrate adjacent to the second side prior to deposition of the tunnel dielectric, which electrically conductive region comprises dopant of the same polarity as the doped polysilicon layer. In an alternative or additional embodiment, a further doped polysilicon layer is provided onto the second side of the substrate prior to deposition of the tunnel dielectric. Suitably, the further doped polysilicon layer is deposited by alternate deposition of first layers and second layers, which first layers predominantly contain silicon and which second layers contain dopant. Preferably, the further doped polysilicon layer, the tunnel dielectric and the doped silicon layer are all deposited in a single reaction chamber.

In a tenth aspect that can be combined with any of the preceding aspects, the tunnel dielectric and the doped silicon layer is provided on the first side of the substrate, as an emitter contact. In one implementation, the method comprises the steps of (1) providing a passivation, at least on the first side; (2) locally opening the passivation at least on the first side; (3) applying the tunnel dielectric; (4) providing the doped polysilicon layer; (5) applying a masking layer in accordance with a predefined pattern; (6) etching away the doped polysilicon layer that is not masked. Preferably, the masking layer is applied by local deposition of a metallic contact, for instance by printing metal paste.

In an eleventh aspect that can be combined with any of the preceding aspects, a further treatment onto the substrate or the polysilicon layer is carried out between the deposition of the multilayer stack and the anneal. Suitably, the further treatment comprises selectively introducing second dopant into the multilayer stack, which second dopant has a polarity opposite to that of the—first—dopant of the second sublayers, wherein the second dopant is introduced into the multilayer stack in a dopant concentration so as to at least compensate, in a first region, the first dopant. Preferably, the further treatment comprises selectively removing the multilayer stack. In one further implementation, the further treatment further comprises generating conductive regions into the substrate that is exposed due to the selective removal of the multilayer stack.

In a twelfth aspect, the invention relates to a solar cell obtainable with the method according any of the preceding aspects.

In a thirteenth aspect, the invention relates to a solar cell, comprising a semiconductor substrate provided with a first side and a second side, which first side is intended as main side for receiving light, wherein the substrate is on at least one side provided with a boron doped polysilicon layer that is separated from the substrate through a tunnel dielectric, wherein the doped polysilicon layer comprises a doping profile with a series of doping peaks, corresponding to a location of second dopant sublayers deposited between first silicon sublayers.

In a fourteenth aspect, which can be combined with the preceding two aspects, the doping profile has a local minimum within a first silicon sublayer sandwiched between two adjacent second boron sublayers, wherein the ratio of doping concentration in the doping peak and the local minimum is at most 100, preferably at most 10.

In a fifteenth aspect, which can be combined with any of the preceding three aspects, the doped polysilicon layer is patterned and electrically isolated in lateral directions.

In a sixteenth aspect, which can be combined with any of the preceding four aspects, the doped polysilicon layer has a thickness of at most 600 nm, for instance in the range of 10-500 nm, preferably in the range of 50-300 nm.

In a seventeenth aspect, which can be combined with any of the preceding five aspects, the number of first silicon sublayers is at least two and the number of second boron sublayers is at least one, wherein more preferably the number of first silicon sublayers is at least three and the number of second boron sublayers is at least two, wherein the second boron sublayers are sandwiched between a pair of first silicon sublayers. Preferably, the number of second boron sublayers is in the range of 2-100, preferably 5-50.

In an eighteenth aspect, which can be combined with any of the preceding six aspects, the thickness of a substack of a first silicon sublayer and a second boron sublayer is less than 50 nm. Preferably, the thickness of a second boron sublayer is at most 3 nm upon deposition, preferably at most 1 nm, for instance 0.1-0.5 nm.

In a nineteenth aspect, the invention relates to a Low Pressure Chemical vapour deposition (LPCVD) apparatus comprising a reaction chamber, means to apply a sub-atmospheric pressure in the reaction chamber, a first and a second inlet means for introducing precursor gases into the chamber, which first inlet means is predefined for a silicon precursor gas and which second inlet means is predefined for a dopant precursor gas, which inlet means are provided with valves for controlling the inlet of said silicon precursor gas and said dopant precursor gas, and a controller configured for control of the inlet means, wherein the second inlet means comprises a distributor means coupled to a first and a second inlet into the reaction chamber, and wherein the controller is configured to specify an alternating sequence of first periods in which silicon precursor gas enters the reaction chamber and second periods in which dopant precursor gas enters the reaction chamber, said sequence of first and second periods comprising at least one first period and at least one second period and suitably thereafter at least one further first period and optionally further second periods and first periods.

In a twentieth aspect that can be combined with the preceding aspect, the reaction chamber is further provided with third inlet means for oxygen gas, and wherein the controller is configured for controlling the generation of a tunnel oxide.

In a twenty-first aspect that can be combined with any of the preceding two aspects, removal means for removing gases from the reaction chamber are present.

In a twenty-second aspect that can be combined with any of the preceding three aspects, the reaction chamber is a reaction chamber of the horizontal type, especially suitable for use in solar cell manufacture.

In a twentythird aspect, the invention relates to a system of a chemical vapour deposition apparatus of the preceding aspects and a waferboat. Preferably, the waferboat is configured for arranging individual substrates at a spacing of at most 8 mm, more preferably at most 5 mm.

1. A method of a manufacturing a solar cell, comprising the steps of:
Providing a semiconductor substrate with a first and a second side, which first side is intended as main side for receiving light;
providing a tunnel dielectric on at least one side of the substrate,
providing a layer of doped polysilicon onto the substrate, separated from the substrate by the tunnel dielectric, and
further processing of the substrate into a solar cell
wherein the provision of the doped polysilicon layer comprises depositing, by means of Low Pressure Chemical Vapour Deposition (LPCVD), a multilayer stack of first sub-layers and second dopant sub-layers in alternation, and subsequent annealing of the multilayer stack into the doped polysilicon layer, which first sublayers predominantly contain silicon and which second dopant sublayers contain boron.

2. The method as claimed in claim 1, wherein the multilayer stack comprises 2-200, preferably 5-100 dopant sub-layers.

3. The method as claimed in claim 1, wherein the alternating deposition of first and second sublayers occurs within a single reaction chamber through variation of injection of precursor gases into the reaction chamber.

4. The method as claimed in claim 3, wherein silicon precursor gas is introduced into the reaction chamber in first periods and dopant precursor gas is introduced in second periods, wherein the second periods are shorter than the first periods, preferably at most 10% of the first periods, wherein the introduction of silicon precursor gas is preferably discontinued during the second periods, and wherein the reaction chamber is preferably emptied, at least substantially from silicon precursor gas prior to the introduction of dopant precursor gas.

5. The method as claimed in claim 1, wherein a single deposition process is carried out for a batch of semiconductor substrates, wherein adjacent semiconductor substrates are arranged at a spacing of at most 8 mm, more preferably at most 5 mm.

6. The method as claimed in claim 1, wherein the tunnel dielectric is a thermally grown oxide that is grown in the same reaction chamber wherein the multilayer stack of the doped polysilicon is deposited.

7. The method as claimed in claim 1, wherein the doped polysilicon layer is provided on the second side of the substrate.

8. The method as claimed in claim 7, wherein an electrically conductive region is applied into the substrate adjacent to the second side prior to deposition of the tunnel dielectric, which electrically conductive region comprises dopant of the same polarity as the doped polysilicon layer.

9. The method as claimed in claim 1, wherein a further treatment onto the substrate or the polysilicon layer is carried out between the deposition of the multilayer stack and the anneal, wherein the further treatment for instance comprises selectively introducing second dopant into the multilayer stack, which second dopant has a polarity opposite to that of the—first—dopant of the second sublayers, wherein the second dopant is introduced into the multilayer stack in a dopant concentration so as to at least compensate, in a first region, the first dopant.

10. A solar cell obtainable with the method according to claim 1.

11. A solar cell as claimed in claim 10, comprising a semiconductor substrate provided with a first side and a second side, which first side is intended as main side for receiving light, wherein the substrate is on at least one side provided with a boron doped polysilicon layer that is separated from the substrate through a tunnel dielectric, wherein the doped polysilicon layer comprises a doping profile with a series of doping peaks, corresponding to a location of second dopant sublayers deposited between first silicon sublayers.

12. The solar cell as claimed in claim 11, wherein the doping profile has a local minimum within a first silicon sublayer sandwiched between two adjacent second boron sublayers, wherein the ratio of doping concentration in the doping peak and the local minimum is at most 100, preferably at most 10.

13. The solar cell as claimed in claim 11, wherein the doped polysilicon layer has a thickness of at most 600 nm, for instance in the range of 10-500 nm, preferably in the range of 50-300 nm.

14. The solar cell as claimed in claim 11, wherein the number of first silicon sublayers is at least two and the number of second boron sublayers is at least one, wherein more preferably the number of first silicon sublayers is at least three and the number of second boron sublayers is at least two, wherein the second boron sublayers are sandwiched between a pair of first silicon sublayers, and wherein the number of second boron sublayers is for instance in the range of 2-100, preferably 5-50.

15. The solar cell as claimed in claim 11, wherein the thickness of a substack of a first silicon sublayer and a second boron sublayer is less than 50 nm, and wherein the thickness of a second boron sublayer is preferably at most 3 nm upon deposition, preferably at most 1 nm, for instance 0.1-0.5 nm.
